(19) United States
(12) Patent Application Publication
(10) Pub. No.: US 2020/0233462 A1
(43) Pub. Date: Jul. 23, 2020

(54) ELECTRONIC DEVICE

(71) Applicant: FUJITSU CLIENT COMPUTING LIMITED, Kanagawa (JP)

(72) Inventors: Shintaro Ohishi, Kawasaki (JP); Takashi Abe, Kawasaki (JP); Takashi Iijima, Kawasaki (JP)

(73) Assignee: FUJITSU CLIENT COMPUTING LIMITED, Kanagawa (JP)

(21) Appl. No.: 16/715,446

(22) Filed: Dec. 16, 2019

(30) Foreign Application Priority Data
Jan. 17, 2019 (JP) 2019-006132

(51) Int. Cl. G06F 1/16; H05K 5/00; H05K 5/03

(52) U.S. Cl. CPC G06F 1/1643; H05K 5/0017; G06F 1/1698; G06F 1/1616; G06F 1/1681; H05K 5/03

(57) ABSTRACT

An electronic device includes: a display; a housing including a first cover that covers an end of the display; a panel that is supported by a first face of the first cover and covers the display; and an elastic member that is bonded with the first face, faces a first end face of the panel, extends along the first end face crossing a front face of the panel, and protrudes beyond the front face. The first face is on an opposite side of the display.

### CROSS-REFERENCE TO RELATED APPLICATIONS

This application is based upon and claims the benefit of priority from Japanese Patent Application No. 2019-006132, filed Jan. 17, 2019, the entire contents of which are incorporated herein by reference.

### FIELD

Embodiments described herein relate generally to an electronic device.

### BACKGROUND

Electronic devices are known, which include a display, a housing with a cover that covers the end of the display, and a panel supported by the surface of the cover opposite to the display to cover the display.

It is beneficial to provide such an electronic device of a novel structure that can protect the panel, for example.

### SUMMARY

According to one aspect of this disclosure, in general, an electronic device includes a display; a housing including a first cover that covers an end of the display; a panel that is supported by a first face of the first cover and covers the display, the first face being on an opposite side of the display; and an elastic member that is bonded with the first face, faces a first end face of the panel, extends along the first end face, and protrudes beyond a front face of the panel, the first end face crossing the front face.

### BRIEF DESCRIPTION OF THE DRAWINGS

FIG. 1 is an exemplary perspective view of the front side of an electronic device according to an embodiment, with a display housing being in a closed position;

FIG. 2 is an exemplary perspective view of the front side of the electronic device of the embodiment, with the display housing being in a first opened position;

FIG. 3 is an exemplary perspective view of the rear side of the electronic device of the embodiment, with the display housing being in a second opened position;

FIG. 4 is an exemplary perspective view of the rear side of the electronic device of the embodiment, with the display housing being in a third opened position;

FIG. 5 is a sectional view of FIG. 4 taken along V to V line;

FIG. 6 is an exemplary sectional view of an electronic device according to a first modification of the embodiment; and

FIG. 7 is an exemplary sectional view of an electronic device according to a second modification of the embodiment.

### DETAILED DESCRIPTION

The following will describe an exemplary embodiment and modifications. The configurations or structures of the embodiment and the modifications described below and functions and effects brought about by the configurations or structures are merely exemplary. The embodiment and modifications can be implemented by other configurations or structures than those disclosed herein. The embodiment and modifications can attain at least one of the effects including derivative effects) attained by the configurations or structures.

The following embodiment and modifications include same or similar components or elements. In the following, such components or elements are denoted by common reference numerals and overlapping description thereof is omitted. Throughout this disclosure, ordinal numbers are used to distinguish, parts, components, materials, locations, positions, orientations, and else, but are not intended to indicate order or priority.

### EMBODIMENT

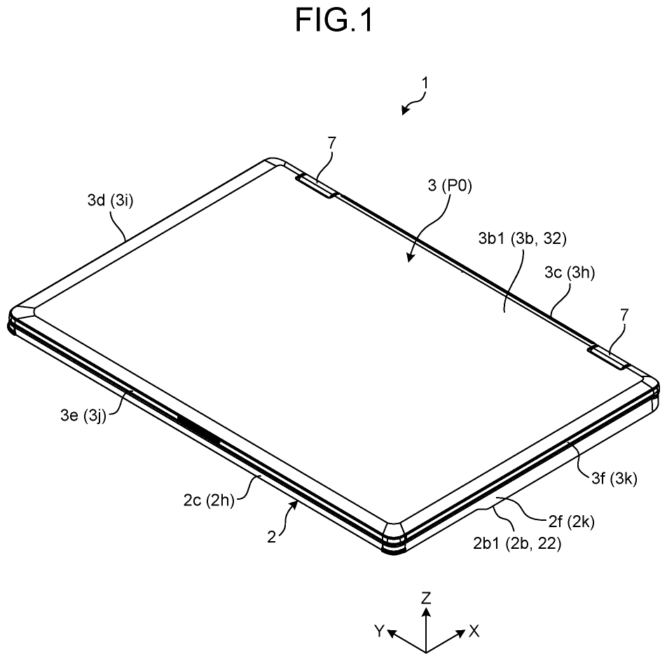

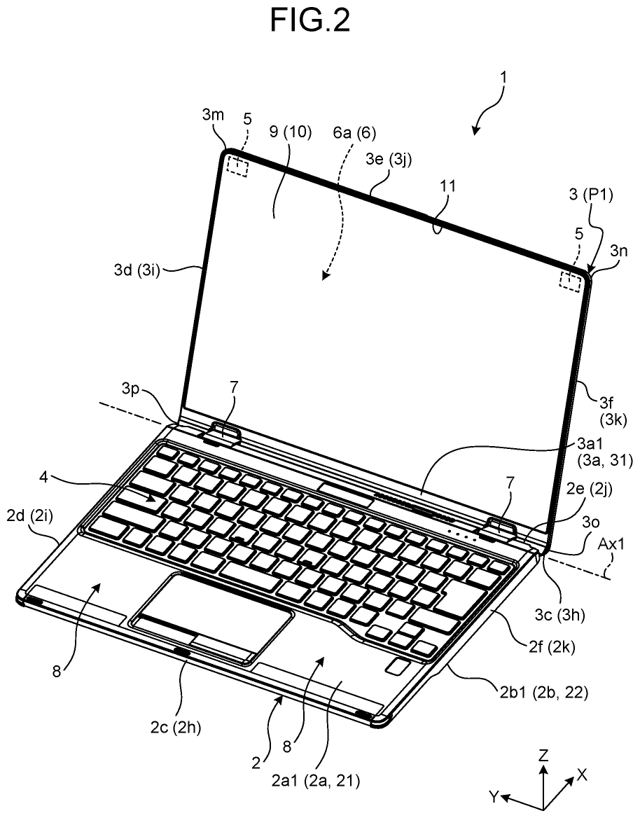

FIG. 1 is a perspective view of the front side of an electronic device 1 with a display housing 3 being in a closed position P0. FIG. 2 is a perspective view of the front side of the electronic device 1 with the display housing 3 being in a first opened position P1.

As illustrated in FIGS. 1 and 2, the electronic device 1 is, for example, a clamshell or notebook personal computer, and includes a base housing 2 and the display housing 3. The base housing 2 accommodates, for example, a keyboard 4 being an input device and a substrate (not illustrated). The display housing 3 accommodates, for example, antennas 5 and a display 6. The display housing 3 is an exemplary housing. The electronic device 1 is not limited to this example, and may be a tablet computer, a smartphone, a mobile phone, or a game machine, for example.

In the following, three mutually orthogonal directions are defined for the sake of convenience. An X-direction is along the depth (front to rear) of the base housing 2, a Y-direction is along the width (in horizontal or longitudinal direction) of the base housing 2, and a Z-direction is along the thickness (in vertical direction) of the base housing 2. The X-direction may be referred to as rearward, a direction opposite to the X-direction may be referred to as frontward. The Y-direction may be referred to as leftward and a direction opposite to the Y-direction may be referred to as rightward. The Z-direction may be referred to as upward and a direction opposite to the Z-direction may be referred to as downward.

The base housing 2 has, for example, a top face 2a1 from which the keyboard 4 is exposed and a bottom face 2b1 opposite to the top face 2a1. The keyboard 4 is supported by the base housing 2 in an operable state from above. The base housing 2 accommodates a substrate on which a plurality of electronic components is mounted, such as a central processing unit (CPU), a read only memory (ROM), and a random access memory (RAM). Wiring and these electronic components mounted on the substrate constitute at least part of a control circuit of the electronic device 1.

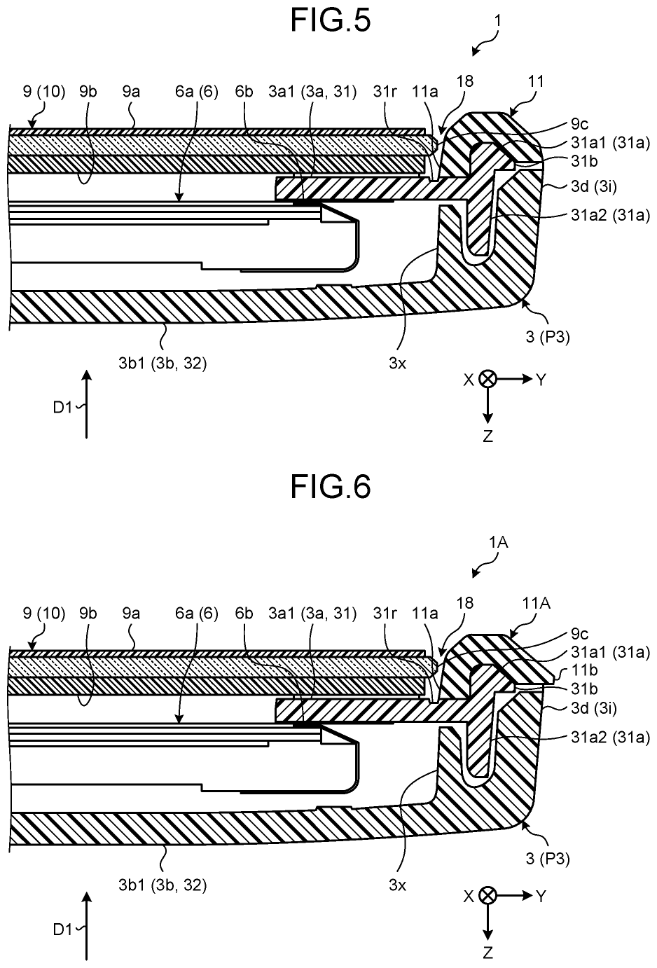

The display housing 3 has, for example, a front face 3a1 from which a display screen 6a (see FIG. 5) of the display 6 is exposed and a rear face 3b1 opposite to the front face 3a1. The display 6 is supported by the display housing 3 such that the display screen 6a is visible from the front side. Part of the front face 3a1 and the display screen 6a are covered with a touch panel 9 of a display unit 10, which will be described later.

The antennas 5 are located at, for example, the lateral ends of a top end 3j of the display housing 3. The antennas 5 are electrically connected to a communication chip on the substrate via cables. The antennas 5 are exemplary diversity antennas. In the present embodiment, the antennas 5 receive the same radio signals, and the electronic device 1 preferentially employs the signals of the antenna 5 in better radio wave condition or combines the received signals to remove noise, to thereby improve communication quality and reliability. The antennas 5 are not limited to this example. For example, a single antenna 5 may be disposed in the center of the top end 3j or at one of the lateral ends.

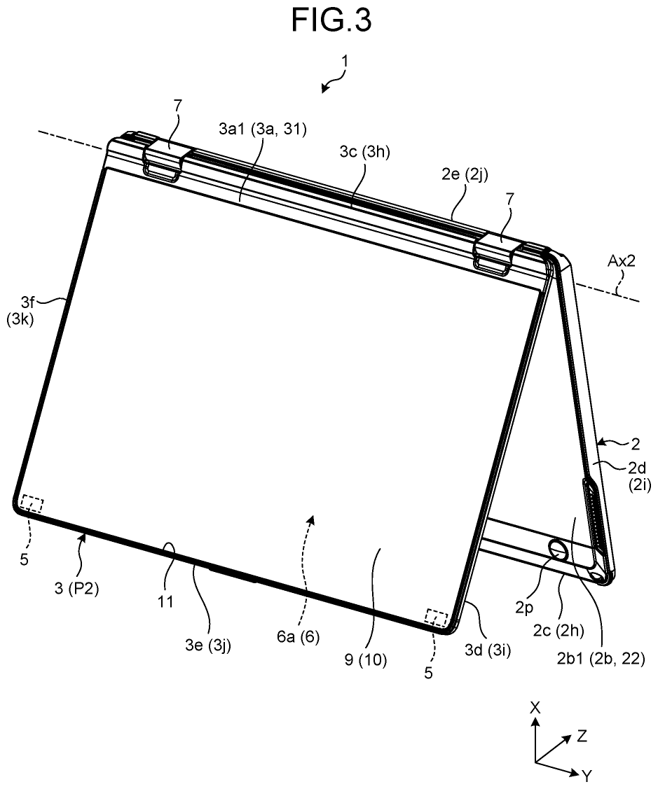

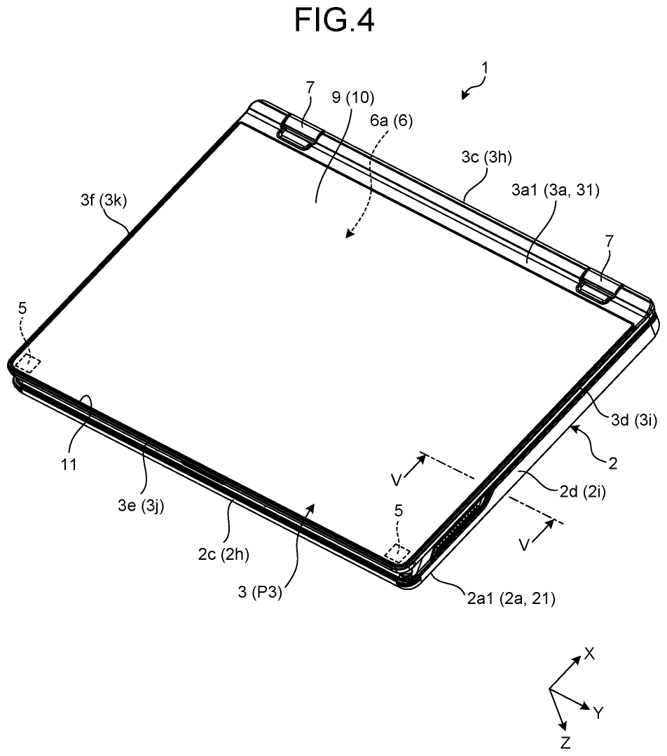

FIG. 3 is a perspective view of the rear side of the electronic device 1 with the display housing 3 being in a second opened position P2. FIG. 4 is a perspective view of the rear side of the electronic device 1 with the display housing 3 being in a third opened position P3. In the present embodiment, the electronic device 1 is usable in various modes such as a notebook mode illustrated in FIG. 2, a tent mode or standing mode illustrated in FIG. 3, and a slate mode or tablet mode illustrated in FIG. 4.

Specifically, the display housing 3 is rotatably supported by the base housing 2 via hinges 7 having two centers of rotation Ax1 and Ax2 or rotational axes extending in the Y-direction. The display housing 3 is movable among the closed position P0 (FIG. 1), the first opened position P1 (FIG. 2), the second opened position P2 (FIG. 3), and the third opened position P3 (FIG. 4) while rotated about the centers of rotation Ax1 and Ax2 of the hinges 7.

As illustrated in FIG. 1, in the closed position P0 of the display housing 3, the top face 2a1 of the base housing 2 and the keyboard 4 oppose the front face 3a1 of the display housing 3 and the display screen 6a of the display 6. In the closed position P0, the components such as the keyboard 4 and the touch panel 9 are hidden by the base housing 2 and the display housing 3 and are therefore inoperable. The closed position P0 may be referred to as an default position or a first folded position.

As illustrated in FIG. 2, in the first opened position P1 of the display housing 3, the top face 2a1 and the keyboard 4 do not oppose the front face 3a1 or the display screen 6a, and the top face 2a1, palm rests 8, the keyboard 4, the front face 3a1, and the display screen 6a are exposed. In the first opened position P1, the rotation angle of the display housing 3 relative to the base housing 2 is, for example, from 90 to 170 degrees. In the first opened position P1, the electronic device 1 is used in a notebook mode through the manipulation of the keyboard 4 in the base housing 2 placed on a mount (not illustrated) such as a desk, a rack, or a stand. The first opened position P1 may be referred to as a first use position.

As illustrated in FIG. 3, in the second opened position P2 of the display housing 3, the top face 2a1 and the keyboard 4, and the front face 3a1 and the display screen 6a face in opposite directions. In the second opened position P2, the rotation angle of the display housing 3 relative to the base housing 2 is, for example, from 270 to 350 degrees. In the second opened position P2, the electronic device 1 is used in a tent mode or standing mode through the manipulation of the touch panel 9 while the base housing 2 and the display housing 3 stand on the mount (not illustrated). The second opened position P2 may be referred to as a second use position, for example.

As illustrated in FIG. 4, in the third opened position P3 of the display housing 3, the top face 2a1 and the keyboard 4, and the front face 3a1 and the display screen 6a face in opposite directions. In the third opened position P3, the rotation angle of the display housing 3 relative to the base housing 2 is 360 degrees. In the third opened position P3, the electronic device 1 is used in a slate mode or tablet mode through the manipulation of the touch panel 9 while the base housing 2 is placed on the mount (not illustrated) or is held up from the mount.

The third opened position P3 is not limited to this example. In the third opened position P3 the display screen 6a of the display housing 3 may be folded back from the top face 2a1 (see FIG. 2) of the base housing 2 via the hinges having two crossing or orthogonal centers of rotation, to face oppositely to the top face 2a1, for example. The third opened position P3 may be referred to as a third use position or a second folded position, for example.

As illustrated in FIG. 2, the base housing 2 has, for example, a flat, rectangular parallelepiped or box shape in the Z-direction. The base housing 2 includes a plurality of walls such as an upper wall 2a, a lower wall 2b, a front wall 2c, a left wall 2d, a rear wall 2e, and a right wall 2f. The front wall 2c, the left wall 2d, the rear wall 2e, and the right wall 2f are also referred to as sidewalls, peripheral walls, or upright walls.

The upper wall 2a and the lower wall 2b extend in a direction orthogonal to the Z-direction, or along an XY plane, and are spaced apart from each other in parallel in the Z-direction. The upper wall 2a includes the top face 2a1 and the lower wall 2b includes the bottom face 2b1. The bottom face 2b1 is provided with a plurality of supports 2p (see FIG. 3) for supporting the base housing 2 away from the mount (not illustrated). The supports 2p are also referred to as, for example, legs or rubber legs.

The front wall 2c and the rear wall 2e extend in a direction orthogonal to the X-direction, or along an YZ plane, and are spaced apart from each other in parallel in the X-direction. The front wall 2c and the rear wall 2e serve as a front end 2h and a rear end 2j of the base housing 2, respectively. The front end 2h is away from the centers of rotation Ax1 and Ax2 of the hinges 7. The rear end 2j is adjacent or close to the centers of rotation Ax1 and Ax2 of the hinges 7 relative to the front end 2h.

The left wall 2d and the right wall 2f extend in a direction orthogonal to the Y-direction, or along an XZ plane, and are spaced apart from each other in parallel in the Y-direction. The left wall 2d extends between the Y-directional ends of the upper wall 2a and the lower wall 2b, and the right wall 2f extends between the opposite ends of the upper wall 2a and the lower wall 2b in the Y-direction. The left wall 2d and the right wall 2f serve as a left end 2i and a right end 2k of the base housing 2, respectively.

The base housing 2 is made of a combination of a plurality of parts or divided members. Specifically, the base housing 2 includes, for example, a top cover 21 and a bottom cover 22. The top cover 21 includes the upper wall 2a, and part of the front wall 2c, the left wall 2d, the rear wall 2e, and the right wall 2f. The bottom cover 22 includes the lower wall 2b, and part of the front wall 2c, the left wall 2d, the rear wall 2e, and the right wall 2f. The top cover 21 and the bottom cover 22 are joined together with fasteners or screws, for example.

As illustrated in FIG. 2, the display housing 3 has, for example, a flat, rectangular parallelepiped shape in a certain direction, e.g., in the X-direction in FIG. 2. The display housing 3 includes a front wall 3a, a rear wall 3b, and sidewalls 3c to 3f. The front wall 3a includes the front face 3a1 and the rear wall 3b includes a rear face 3b1. The front wall 3a has a rectangular frame shape and the rear wall 3b has a rectangular plate shape.

The sidewall 3c and the sidewall 3e serve as a bottom end 3h and the top end 3j of the display housing 3, respectively. The bottom end 3h is adjacent or close to the centers of rotation Ax1 and Ax2 of the hinges 7. The top end 3j is further away from the centers of rotation Ax1 and Ax2 of the hinges 7 than the bottom end 3h. The sidewall 3d and the sidewall 3f serve as a left end 3i and a right end 3k of the display housing 3, respectively.

The display housing 3 has four corners 3m to 3p. The corner 3m is defined by the intersection between the left end 3i and the top end 3j, and the corner 3n is defined by the intersection between the top end 3j and the right end 3k. The corner 3o is defined by the intersection between the right end 3k and the bottom end 3h, and the corner 3p is defined by the intersection between the bottom end 3h and the left end 3i. The corners 3m to 3p are rounded corners.

The display housing 3 is made of a combination of parts or divided members. Specifically, the display housing 3 includes, for example, a front cover 31 and a rear cover 32. The front cover 31 includes the front wall 3a and part of the sidewalls 3c to 3f. The rear cover 32 includes the rear wall 3b and part of the sidewalls 3c to 3f. The front cover 31 and the rear cover 32 are joined together with fasteners or screws, for example.

The following describes the display unit 10 in detail. FIG. 5 is a sectional view of FIG. 4 taken along V to V line. As illustrated in FIG. 5, the display unit 10 includes, for example, the display 6, the front cover 31, the touch panel 9, and an elastic member 11. The display 6, the front cover 31, and the touch panel 9 are joined or assembled together with, for example, an adhesive or a double-sided tape.

The display 6 is, for example, a liquid crystal display (LCD). The display 6 has a flat, rectangular parallelepiped shape in a D1 direction crossing the front face 3a1. The display screen 6a of the display 6 is covered with a transparent part of the touch panel 9. The display 6 is not limited to this example, and may be an organic electro-luminescent display (OELD) as an example. For another example, the touch panel 9 may be an in-cell touch panel incorporated into the display 6.

The front cover 31 has a rectangular frame shape to cover a periphery 6b of the display 6. The front face 3a1 of the front cover 31 supports the touch panel 9. The front cover 31 is an exemplary first cover and the front face 3a1 is an exemplary first face. The periphery 6b is an exemplary end. The front cover 31 is made of a synthetic resin.

The touch panel 9 has a thin rectangular form to cover the display 6. The touch panel 9 includes a plurality of layers laminated in the D1 direction, such as a glass layer, a sensor layer, and a protection layer. The touch panel 9 is an exemplary panel. The panel is not limited to this example, and may be a glass panel or an acrylic panel, for example.

The touch panel 9 has a front face 9a, a back face 9b, and four end faces 9c. The end faces 9c extend between the front face 9a and the back face 9b, crossing the front face 9a. In the present embodiment, three of the four end faces 9c face the elastic member 11 with spacing. The end faces 9c are an exemplary first end face.

The elastic member 11 extends along the three end faces 9c of the touch panel 9 corresponding to the left end 3i, the top end 3j (see FIG. 2), and the right end 3k of the front cover 31. In other words, the overall elastic member 11 substantially has a U-shape that opens toward the bottom end 3h and the hinges 7. The elastic member 11 surrounds the three end faces 9c of the touch panel 9. The elastic member 11 may surround the four end faces 9c corresponding to the left end 3i, the top end 3j, the right end 3k, and the bottom end 3h, for example.

The elastic member 11 is made from, for example, elastomer or rubber. In the present embodiment, the elastic member 11 is bonded or integrated with the front face 3a1 of the front cover 31 by, for example, two-material or two-color molding. Thereby, the bonding surfaces of the elastic member 11 and the front cover 31 are fused.

The elastic member 11 protrudes beyond the front face 9a of the touch panel 9 in the D1 direction, that is, in a direction away from the inner surface of the rear wall 3b. This prevents the touch panel 9 and the base housing 2 from contacting each other in the closed position P0 (see FIG. 1) of the display housing 3.

The elastic member 11 has a sloping face 11a. The sloping face 11a faces the end faces 9c of the touch panel 9 and is inclined away from the end faces 9c as is away from the front face 3a1. In the present embodiment, the end of the sloping face 11a close to the front face 3a1 is located below the touch panel 9 in the D1 direction. This makes a gap 18 between the elastic member 11 and the touch panel 9 less noticeable.

In the present embodiment, the front cover 31 includes an upright wall 31a in the outer periphery. The upright wall 31a protrudes in the D1 direction and in the opposite direction. The upright wall 31a constitutes part (inside part) of the sidewall 3d of the display housing 3. The elastic member 11 covers the circumference of a first end 31a1 of the upright wall 31a. In other words, the elastic member 11 has a substantially U-shaped cross section, opening toward the upright wall 31a. The elastic member 11 is bonded with an outer end face 31b of the upright wall 31a. The end face 31b is an exemplary second end face.

The elastic member 11 is juxtaposed to an end face of the sidewall 3d (i.e., outer part) of the rear cover 32 in the D1 direction. If the electronic device 1 falls with the sidewall 3d down, for example, the elastic member 11 of the present embodiment functions to transmit an impact to the first end 31a1 of the upright wall 31a and to a rib 3x of the rear cover 32 via a second end 31a2 of the upright wall 31a. Thereby, the elastic member 11 can reduce transmission of the impact to the touch panel 9.

The front face 3a1 is provided with a recess 31r opening in the D1 direction. The recess 31r is adjacent to the elastic member 11 and extends in the longitudinal direction of the elastic member 11, that is, along the end faces 9c. The recess 31r can accommodate, for example, the burr formed in the two-material molding of the elastic member 11 and the front cover 31. In the present embodiment, at least part of the recess 31r is located below the touch panel 9 in the D1 direction.

As described above, the electronic device 1 according to the present embodiment includes the display 6, the display housing 3 (housing), the touch panel 9 (panel), and the elastic member 11. The display housing 3 includes the front cover 31 (first cover) that covers the periphery 6b (end) of the display 6. The touch panel 9 is supported by the front face 3a1 (first face) of the front cover 31 opposite the display 6, to cover the display 6. The elastic member 11 is bonded with the front face 3a1, faces the end faces 9c (first end face) of the touch panel 9 crossing the front face 9a, extends along the end faces 9c, and protrudes beyond the front face 9a.

Owing to such a structure, in the closed position P0 (see FIG. 1) of the electronic device 1, for example, the elastic member 11 can work to prevent the touch panel 9 and the base housing 2 from contacting each other, thereby protecting the touch panel 9. In the case of the electronic device 1's dropping with the sidewall 3d down, for example, the elastic member 11 can function as an impact absorber to reduce transmission of the impact to the touch panel 9. In addition, the elastic member 11 can be more firmly bonded with the front cover 31 by two-material or two-color molding than the elastic member 11 attached to the front cover with a double-sided adhesive tape, for example. That is, upon receiving load such as an impact, for example, the elastic member 11 is less likely to move or come off from the front cover 31, to be able to more firmly or surely protect the touch panel 9.

In the present embodiment, the elastic member 11 is also bonded with the end face 31b (second end face) of the front cover 31, the end face 31b that crosses the front face 3a1.

Thereby, the elastic member 11 can be more firmly bonded with the front cover 31 than the elastic member 11 bonded with the front face 3a1 of the front cover 31 alone, for example. In this regard, upon receiving load such as an impact, for example, the elastic member 11 is less likely to move or come off from the front cover 31. In the case of the electronic device 1's falling with the sidewall 3d down, for example, the elastic member 11 can protect the end face 31b.

In the present embodiment, the front face 3a1 is provided with the recess 31r adjacent to the elastic member 11 and opening in the D1 direction (first direction). The recess 31r is located to overlap the touch panel 9 in a view from the D1 direction.

According to such a structure, for example, the recess 31r in the front cover 31, if provided, is hidden by the touch panel 9, which can prevent the electronic device 1 from being impaired in appearance. In addition, for example, providing the recess 31r eliminates the need for removing the burr formed in the two-material or two-color molding of the elastic member 11 and the front cover 31, which results in a higher yield in production.

In the present embodiment, the elastic member 11 has the sloping face 11a that is inclined away from the end faces 9c as is away from the front face 3a1. Part of the sloping face 11a is located to overlap the touch panel 9 in a view from the D1 direction.

Thus, the sloping face 11a serves to make the gap 18 between the elastic member 11 and the touch panel 9 less noticeable or visible, for example. This can improve the design and appearance of the electronic device 1 in the D1 direction. Moreover, the sloping face 11a works to facilitate mounting of the touch panel 9 onto the front cover 31, for example.

### First Modification

FIG. 6 is a sectional view of an electronic device 1A according to a first modification of the embodiment. The electronic device 1A has the same or like structure as the electronic device 1 of the embodiment. In this regard, the electronic device 1A can attain the same or like functions and effects based on the same or like structure as the electronic device 1 of the embodiment.

As illustrated in FIG. 6, the first modification differs from the embodiment above in that the electronic device 1A includes an elastic member 11A having a protrusion 11b. The protrusion 11b protrudes beyond the sidewall 3d of the rear cover 32 oppositely to the end face 9c, i.e., in the Y-direction. The rear cover 32 is an exemplary second cover.

The protrusion 11b extends along the entire width of the elastic member 11A in the longitudinal direction, that is, in a direction along the end face 9c. The protrusion 11b is not limited to this example, and may intermittently extend on the elastic member 11A in the longitudinal direction, for example.

According to the first modification, the protrusion 11b of the elastic member 11A serves to prevent the rear cover 32 or the display housing 3 from contacting the floor in the case of the electronic device 1A's falling with the sidewall 3d down, to be able to protect the display housing 3.

### Second Modification

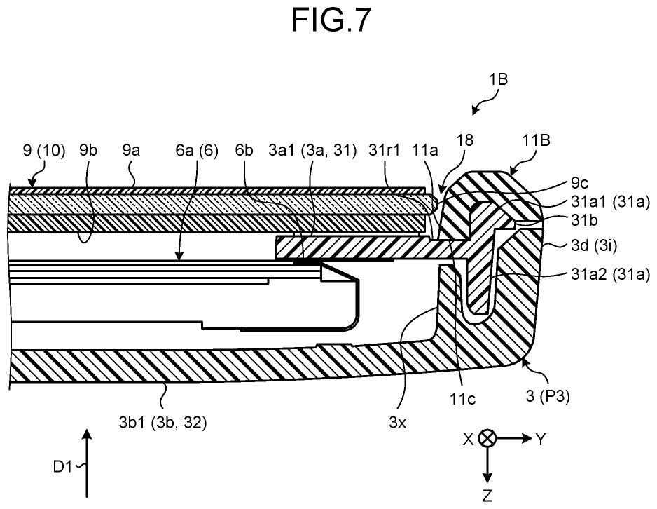

FIG. 7 is a sectional view of an electronic device 1B according to a second modification of the embodiment. The electronic device 1B has the same or like structure as the electronic device 1 of the embodiment. In this regard, the electronic device 1B can attain the same or like functions and effects based on the same or like structure as the electronic device 1 of the embodiment.

As illustrated in FIG. 7, the second modification differs from the embodiment in that the electronic device 1B includes an elastic member 11B having an extension 11c. In the second modification, the elastic member 11B and a recess 31r1 are juxtaposed to each other in the D1 direction. The extension 11c extends toward the bottom surface of the recess 31r1 and is accommodated in the recess 31r1. The end of the recess 31r1 opposite to the upright wall 31a is located below the touch panel 9 in the D1 direction.

According to the second modification, the front cover 31 is provided with the recess 31r1 of a given width sufficient to accommodate the extension 11c. This can reduce labor and time for forming the recess 31r1.

According to one aspect, it is possible to provide an electronic device of a novel structure that can protect a panel.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic device comprising:
a display;
a housing comprising a first cover that covers an end of the display;
a panel that is supported by a first face of the first cover and covers the display, wherein the first face is on an opposite side of the display; and
an elastic member that is bonded with the first face, faces a first end face of the panel, extends along the first end face, and protrudes beyond a front face of the panel, the first end face crossing the front face.

2. The electronic device according to claim 1, wherein
the elastic member is bonded with a second end face of the first cover, and
the second end face crosses the first face.

3. The electronic device according to claim 1, wherein
the housing comprises a second cover that covers a side of the display,
the side of the display is opposite to a panel side, and
the elastic member comprises a protrusion that protrudes beyond the second cover oppositely to the first end face.

4. The electronic device according to claim 1, wherein
the first face is provided with a recess,
the recess is adjacent to the elastic member and opens in a first direction crossing the first face, and
the recess overlaps the panel when viewed from the first direction.

5. The electronic device according to claim 1, wherein
the elastic member includes a sloping face that is inclined away from the first end face as is away from the first face, and
the sloping face overlaps the panel when viewed from a first direction crossing the first face.
